(19) United States
(12) Patent Application Publication
(10) Pub. No.: US 2024/0166052 A1
(43) Pub. Date: May 23, 2024

(54) Method for checking an insulation state of a battery or battery system

(71) Applicant: Webasto SE, Stockdorf (DE)

(72) Inventors: Julian Nowroth, Stockdorf (DE); Ivan Liu Zhu, Stockdorf (DE)

(21) Appl. No.: 18/282,682

(22) PCT Filed: Mar. 21, 2022
(86) PCT No.: PCT/EP2022/057306

§ 371 Date: Sep. 18, 2023

(30) Foreign Application Priority Data
Mar. 19, 2021 (DE) 10 2021 106 891.6

(51) Int. Cl. B60L 3/00; G01R 19/257; G01R 27/14; G01R 27/26

(52) U.S. Cl. CPC B60L 3/0046; B60L 3/0069; G01R 19/257; G01R 27/14; G01R 27/2605; B60L 2240/547; B60L 2250/10

(57) ABSTRACT

A method for checking an insulation state of a battery or battery system comprising at least two batteries, comprising the following steps: measuring a voltage between a connection element of the battery and a ground over a predefined time; evaluating the measured voltage and determining whether a change in the measured voltage is present at time point that corresponds to a predefined temporal threshold value; and outputting a safety signal characterizing the insulation state on the basis of the established result.

### CROSS-REFERENCE TO RELATED APPLICATIONS

This application is a 35 U.S.C. § 371 National Stage Entry of International Application No. PCT/EP2022/057306 filed Mar. 21, 2022, which claims the priority benefit of German Patent Application Serial Number DE 10 2021 106 891.6 filed Mar. 19, 2021, all of which are incorporated herein by reference in their entirety for all purposes.

### TECHNICAL FIELD

The present invention relates to a method for checking an insulation state of a battery or battery system, preferably of a high-voltage battery or high-voltage battery system for use as traction battery of an electric vehicle or for use in static storage applications, and to a corresponding device.

### BACKGROUND

The use of high-voltage batteries, for example for electric vehicles, requires checking the insulation state of the high-voltage battery before they are switched on or connected together to form a battery system in order to be subsequently connected to a load. In a normal state in an electric vehicle, in which the high-voltage battery is preferably arranged as traction battery, there is galvanic isolation between the high-voltage battery and ground or the chassis, such that, when the high-voltage battery is switched on, a short circuit does not occur and it may be ensured that the user is not exposed to any potentially life-threatening electric shock and also the other electronics of the vehicle are not damaged. When high-voltage batteries are connected together to form a high-voltage battery system, it is particularly important that the high-voltage batteries to be connected together are insulated from ground, since otherwise a short circuit to ground could already arise when the high-voltage batteries are connected together and this could hence result in uncontrollably high currents and thus in destruction of the high-voltage batteries and a risk to the user.

An insulation check is usually carried out based on a calculated insulation resistance between the high-voltage battery and ground, for example the chassis of an electric vehicle, following the application of a high voltage at a low current. For reliable calculation, it is necessary to measure a stable voltage, that is to say voltage saturation, but this occurs only after a relatively long time, for example after around 7 to 10 seconds. Accordingly, the check, in particular when it is carried out for multiple connections or lines of the high-voltage battery and depending on the configuration of the high-voltage battery and the hardware and software level, may require up to 30 seconds or even more. Such a long time to start a vehicle is undesirable. Shortening this checking time for a respective connection, however, impairs the accuracy and the measurable range of the calculated resistance.

Nevertheless, it is generally undesirable for the user of the high-voltage battery or of an electric vehicle to wait for relatively long checking times to determine the insulation state, since this leads to a (considerable) delay with regard to the respective use of the high-voltage battery and thus the use of the vehicle.

Hence, a need exists to ensure the safety of the user and nevertheless to provide a fast insulation check.

### SUMMARY

Starting from the known prior art it is an object of the present invention to provide an improved method for checking an insulation state of a battery as well as a corresponding checking module and a corresponding system.

Said object is achieved by a method for checking an insulation state of a battery having the features of claim 1. Advantageous embodiments are derivable from the dependent claims, the description and the Figures.

Accordingly, a method for checking an insulation state of a battery, preferably a battery of a battery system, and particularly preferably a high-voltage battery, is suggested, comprising the following steps:
measuring a voltage between a connection element of the battery and a ground over a predefined time;
evaluating the measured voltage and determining whether a change in the measured voltage is present at a time point that corresponds to a predefined temporal threshold value; and
outputting a safety signal characterizing the insulation state on the basis of the determined result.

According to the invention, it has been recognized that the saturation time of the voltage is dependent on the capacitance being present and the resistance being present. In the event of an insulation fault in which a low resistance is present, or in the event of a low parasitic capacitance, fast voltage saturation occurs. In accordance, it follows that, when the voltage saturation has occurred, no further voltage change is measured.

The suggested method accordingly enables to determine or predefine a temporal threshold value that is a measure of the insulation state and is in particular selected such that serious insulation faults are able to be detected or determined on the basis of the temporal threshold value. In the event of a short circuit or defective insulation, fast saturation of the measured voltage occurs. If at a time point corresponding to the temporal threshold value no further voltage change is measured or detected, then it is assumed that voltage saturation has already occurred and the safety signal may accordingly indicate an insulation fault. Conversely, (serious) insulation faults are ruled out with a sufficient probability if, at the time point of the temporal threshold value, a voltage change is still measured or detected and hence voltage saturation has not yet occurred.

The temporal threshold value may thus correspond to a particular safety measure and/or a predefined insulation state or insulation fault. The use of the temporal threshold value thus has the advantage that it is not necessary to carry out a complete checking and calculation of the resistance according to standards for certain insulation faults. These insulation faults may instead already be ruled out or identified after a short time based on a measured voltage change at the time point of the temporal threshold value. Thus, for example in the event of defective galvanic isolation between the battery and a chassis, representing a ground, of the electric vehicle, voltage saturation already occurs within the temporal threshold value.

The checking time for the insulation state for the connection element is thereby predefined essentially by the temporal threshold value and may be between around 0.3 seconds and 2 seconds, in particular between 0.4 seconds and 0.8 seconds, depending on the configuration of the battery and the predefined threshold value for a insulation fault (for example 500 ohms/volts). The waiting time for the user is thereby reduced considerably or is imperceptible to any significant extent to the user, such that undesired waiting times may be avoided and no substantial delay is present in the application. At the same time, sufficient safety for the user is ensured, since the temporal threshold value is determinative for example for a particular safety measure and/or a predefined insulation fault.

The ground may be any ground that enables grounding or zeroing. In the case of a battery for an electric vehicle, the ground may in particular be the chassis of the electric vehicle. As an alternative, however, a conductive housing having appropriate properties may also be selected. The battery here is preferably a traction battery of an electric vehicle. The insulation check may in particular be used as a safety step for a switching device that is configured to connect the battery to a load, preferably the on-board power system and/or an electric motor, for example via an appropriate switchable disconnector. The safety signal may thus confirm a sufficient insulation state or indicate the presence of a (serious) insulation fault, such that the switching device is able to be switched on the basis of this result. In other words, outputting the safety signal allows to actuate or close the switching device, but only when no (serious) insulation fault has been established.

The battery mentioned here may preferably also be provided for setting up a battery system, wherein at least two batteries are connected together to set up the battery system to hence provide an increased capacity of the combined battery system. The battery system is then used to supply electric power to the load. Preferably, the battery may be present as a high-voltage battery, which may then be connected together with at least one further high-voltage battery to form a high-voltage battery system and be subsequently used, for example, for use as a traction battery of an electric vehicle or for use in static storage applications. The safety signal may thus confirm a sufficient insulation state or indicate the presence of a (serious) insulation fault, such that a switching device for connecting the batteries or the high-voltage batteries together is able to be switched on the basis of this result. In other words, outputting the safety signal allows to actuate or close the switching device, but only when no (serious) insulation fault has been determined. If, by contrast, a (serious) insulation fault has been determined, the corresponding battery may not be connected into the battery system or the batteries of the overall battery system may not be connected together or may not be connected to the load.

The connection element may be a connection line of the battery or also a pole or a corresponding contact element or terminal of the battery.

The battery preferably comprises at least two battery modules. In other words, a battery is preferably formed of at least two battery modules, which are each constructed from a plurality of battery cells, which may be provided, for example, as cylindrical or prism-shaped battery cells or be present in the form of pouch cells. The battery is particularly preferably provided with its own battery housing in which the battery modules are accommodated in a fluid-tight manner and in a manner protected from the environment. The battery preferably also comprises devices for controlling the temperature of the battery cells being organized in the battery modules. Each battery has a main connection having two connection contacts or terminals along which the entire capacity of the battery is present. Each battery has a disconnector that is able to disconnect the main connection. The battery is then connected to the load or connected into the battery system by means of the disconnector.

To set up a battery system, at least two batteries that are arranged for example at two different locations in the vehicle—for example one battery in the underfloor area of the vehicle and another battery in the rear of the vehicle—are connected together. Before the batteries are connected together to form the battery system, the insulation state of the batteries has to be checked in order to prevent a short circuit to the common ground.

In the case of two batteries, the insulation state may for example be checked on the basis of the four electrical connection contacts or the connecting lines connected thereto. However, it is preferred that the insulation state is measured and evaluated separately for each connection contact of each battery.

For battery systems having multiple electrically connected batteries, a parasitic capacitance occurs between the batteries due to contact and due to the lines. The batteries themselves also carry a parasitic capacitance. In the normal state in which no insulation fault is present, this is significantly higher compared to an insulation state in which a short circuit is present. In other words, the parasitic capacitance is relatively small in the case of a (serious) insulation fault. This enables to accordingly predefine the temporal threshold value to differentiate between these states, since this has a direct effect on the saturation time of the measured voltage.

The battery system may accordingly comprise at least two batteries, wherein the temporal threshold value is determined by a predefined parasitic capacitance and a predefined resistance.

By way of example, for a battery in the normal state, there may be a maximum parasitic capacitance of around 900 nF, i.e. around 450 nF for each electrical connecting line. The resistance may additionally be assumed to be e.g. 100 kOhm or 150 kOhm in order to provide sufficient safety and for example detect a short circuit that is present with sufficient certainty within the predefined time. A saturation time for the measured voltage is accordingly determined or calculated based on these values of the maximum parasitic capacitance and the resistance. Here, in an application as a battery system for an electric vehicle, the chassis may serve as a ground, which is being defined for example with a resistance of around 500 kOhm for the purpose of calculating the temporal threshold value. The voltage of the battery system or of the batteries is in this case for example around 400 V or 800 V. With the values described above, the calculated temporal threshold value or the corresponding maximum saturation time is roughly between 0.5 and 0.7 seconds.

If it is accordingly established that saturation of the measured voltage is not yet present at a time point that corresponds to the established temporal threshold value, then serious insulation faults may be ruled out with sufficient probability.

The temporal threshold value may be adapted to a provided sampling rate depending on the configuration of the battery and/or the hardware and software level. By way of example, the temporal threshold value, at a sampling rate of 100 ms, may thus comprise 5 or 7 measurement points so as to comprise a corresponding temporal threshold value of between around 0.41 seconds and 0.5 seconds, or of between around 0.61 seconds and 0.7 seconds. The temporal threshold value may in this case be stored or received from a decentralized or central unit via a communication module.

The parasitic capacitance is preferably battery-specific. In this manner it is possible to use the same temporal threshold value for each battery of the same type or same configuration, as a result of which the method may also be implemented easily for existing batteries and battery systems, for example on the software level, and no (significant) adaptations, and in particular no application-specific or battery-specific measurements of the respective parasitic capacitance, are necessary on the hardware level.

The parasitic capacitance is preferably measured and/or calculated or computed for the battery, wherein the parasitic capacitance is preferably increased by a predefined safety factor. The measurement and/or calculation may also be performed for one or more batteries of the same type, for example in the factory, and be determined for batteries of the same type. In other words, according to the method, no active measurement and/or calculation is necessary; rather, the parasitic capacitance is a value that is not determined arbitrarily or purely theoretically, but rather is based on an actual measurement and/or calculation. Preferably, the value for the parasitic capacitance is both measured and calculated, such that for example the calculated value is checked and the safety when using the temporal threshold value being dependent thereon may be further increased.

By way of example, a calculated and/or measured parasitic capacitance may be between around 100 nF and 300 nF. This maximum parasitic capacitance may be increased by an appropriate safety factor in order to improve safety, such that safety when using the corresponding temporal threshold value may be increased by this factor. By way of example, in the event of a measured or calculated parasitic capacitance of around 220 nF, a maximum parasitic capacitance of 450 nF may be selected or chosen, which is accordingly taken as a basis for the calculation of the temporal threshold value.

The resistance used for the temporal threshold value is preferably between 50 kOhm and 250 kOhm, preferably between 75 kOhm and 175 kOhm, depending on the application. In this manner a resistance that is lower than in standard methods may be used. However, such resistance values still offer sufficient safety for the user and also for the battery modules, since serious insulation faults, such as the presence of a short circuit, may thereby be determined. The lower resistance furthermore allows to considerably shorten the insulation check.

The resistance is preferably a predefined starting resistance or a nominal resistance. The temporal threshold value may thus be predefined or predetermined for different operating states.

To increase the accuracy of the determination or detection of a voltage change, it may furthermore be provided that the voltage change is determined for the last two to five measurement points, preferably the last two or three measurement points, and/or wherein a voltage change is determined when it has at least a predefined minimum magnitude.

This enables to average any measurement errors or fluctuations that may be present and to improve the validity of the safety signal that is output. The predefined minimum magnitude enables to take into consideration only relevant voltage values when determining a voltage change and to fade out detected background signals, residual values or noise. By way of example, the minimum magnitude may be between 0.2 V and 1.0 V or about 0.5 V, such that detected measured values below 0.5 V are not detected as a voltage change.

Alternatively or in addition, the safety signal may furthermore be output on the basis of an absolute voltage value measured at the time point. Accordingly, it is possible to detect whether the measured voltage is within an expected and/or predefined range, such that the validity of the measurement and of the voltage change is able to be further increased.

The measured absolute voltage value may accordingly be considered to be valid when, for example, in comparison with a predefined maximum voltage value, for example of a battery module, it is between 10 percent and 70 percent, preferably between 15 percent and 55 percent of the predefined maximum voltage value.

By way of example, the measured absolute voltage value of a battery of around 400 V may be between 40 V and 280 V and is preferably between 60 V and 220 V. Should a voltage change accordingly be determined at the time point of the temporal threshold value, then the absolute voltage value confirms the validity of the established result and may indicate a potential insulation fault or measurement error by way of the safety signal that is output, if it is not within the predefined range.

In the event of a voltage change determined at the time point, the safety signal preferably comprises an actuation signal for a high-voltage switching device or, in the absence of a voltage change, the safety signal preferably initiates a further insulation check, in particular a complete insulation check according to standards.

As described above, the battery system may be designed in particular as a traction battery for an electric vehicle and may accordingly comprise multiple batteries. To protect the user of the vehicle and also the batteries against a potential short circuit, the insulation state is checked before the respective battery is connected to a load such as the on-board power system or an electric motor by way of the high-voltage switching device and potentially a disconnector. If a voltage change continues to be detected at the time point of or during the measurement and upon or immediately after the occurrence of the temporal threshold value, then it is determined that no (serious) insulation fault is present and the battery system is hence able to be connected accordingly to the consumer and an actuation signal may be accordingly output. If, however, it is determined that a voltage saturation has already occurred, then a fault or error message may be output and/or a further insulation check, for example involving determining the resistance as provided according to standards, may immediately be initiated. A further check or an alternative method for determining the insulation state may thereby serve as further safeguard and as backup.

According to a further aspect, a checking module for checking an insulation state of a battery, preferably a traction battery of an electric vehicle, is suggested, wherein the checking module is configured to carry out the described method.

The checking module may, for example, comprise an interface for measuring and/or receiving a measured voltage between a connection element of the battery and a ground over a predefined time. The checking module may furthermore comprise an evaluation unit that is connected to the interface and is configured to evaluate the measured voltage, wherein the evaluation unit is furthermore configured to determine whether there is a change in the measured voltage at a time point that corresponds to a predefined temporal threshold value. The checking module or the evaluation unit of the checking module is furthermore configured to output a safety signal characterizing the insulation state on the basis of the determined result.

The evaluation unit may be a standalone unit of the checking module or at least partially be present in the form of a control unit of the respective application for the battery. In other words, (partial) tasks of the evaluation unit may e.g. be delegated by way of a communicative coupling to a control unit or the evaluation unit may be integrated in the control unit. The evaluation unit may thereby be designed at least in part as an on-board control unit.

The temporal threshold value is furthermore preferably stored in the evaluation unit and is specific to the respective battery. When the voltage measurement is started, for a predefined time, it is accordingly established at the time point of the stored temporal threshold value whether a voltage change is present and the checking module or the evaluation unit outputs a corresponding safety signal.

According to a further aspect of the invention, a battery system is suggested that comprises at least two batteries, preferably for forming a traction battery for an electric vehicle, and a checking module communicatively and/or electrically conductively coupled thereto.

The battery system may e.g. comprise an on-board battery management system. The battery system comprises at least two batteries that are electrically conductively connectable to each other, wherein each battery comprises at least two battery modules, each having a plurality of battery cells. The battery system preferably furthermore comprises a high-voltage switching device that is configured to connect the respective battery into the battery system on the basis of a safety signal output by the checking module and thus to electrically conductively connect the battery system to a load, such as an electric motor or controller of an electric motor.

### BRIEF DESCRIPTION OF THE FIGURES

Preferred further embodiments of the invention will be explained in more detail through the following description of the Figures, in which:

FIGS. 1A and 1B show a schematic depiction of insulation faults in a battery system having two batteries with respect to a chassis in an electric vehicle;

FIG. 2 shows an exemplary voltage measurement curve in the normal state without insulation faults in a conventional method; and

FIGS. 3A and 3B show a schematic illustration of an exemplary voltage measurement curve without and with insulation faults, respectively.

### DETAILED DESCRIPTION

Preferred exemplary embodiments are described below with reference to the Figures. In this case, identical, similar or functionally identical elements in the various Figures are provided with identical reference signs and a repeated description of these elements is in some cases omitted in order to avoid redundancies.

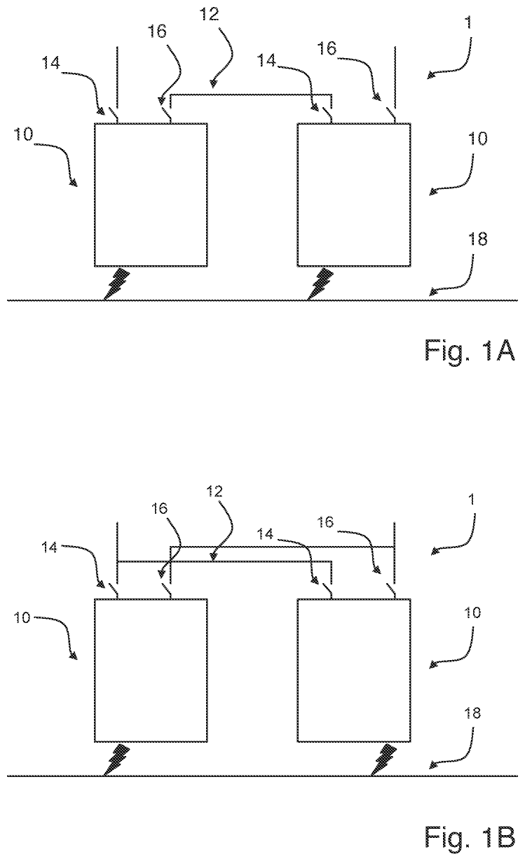

FIG. 1A schematically shows a battery system 1 having two batteries 10, wherein the batteries 10 are electrically conductively connected in series with one another via corresponding connection lines 12 or connection elements. Further connection lines are also provided to electrically conductively connect the battery system or the respective batteries 10 to a load, for example via a disconnector and/or a high-voltage switching device (not shown). Each battery 10 furthermore comprises a positive pole 14 and a negative pole 16, which are able to be electrically coupled by way of the corresponding connection lines.

In the exemplary embodiment, two insulation faults are present, as illustrated by the corresponding lightning symbol. In this example, the insulation or galvanic isolation of the positive pole 14 of the respective battery 10 with respect to the chassis 18 (or other ground) is not complete, meaning that the respective poles 14 are electrically conductively connected to the chassis 18. Even on its own, such an insulation fault with an individual battery 10 with respect to the chassis 18 should be considered problematic and should be avoided.

In the case of providing a battery system 1 in which the batteries 10 are intended to be connected to one another, there is however the additional risk of a short circuit being generated between the batteries 10 via the chassis 18, which may then lead to a high current flow and thus a risk to the batteries 10 and to the user. By way of example, when a conductive connection is established between the positive pole of one battery and the negative pole of the other battery due to the insulation faults with the batteries 10 and the respective other poles are then closed by the high-voltage switching device, an uncontrolled high current flow may occur. Such insulation faults should accordingly be avoided and are detected in accordance with the suggested method.

FIG. 1B illustrates a parallel circuit between the batteries 10. In this example, there is an insulation fault at the positive pole 14 of one battery 10 and an insulation fault at the negative pole 16 of the other battery, as indicated by the corresponding lightning symbol.

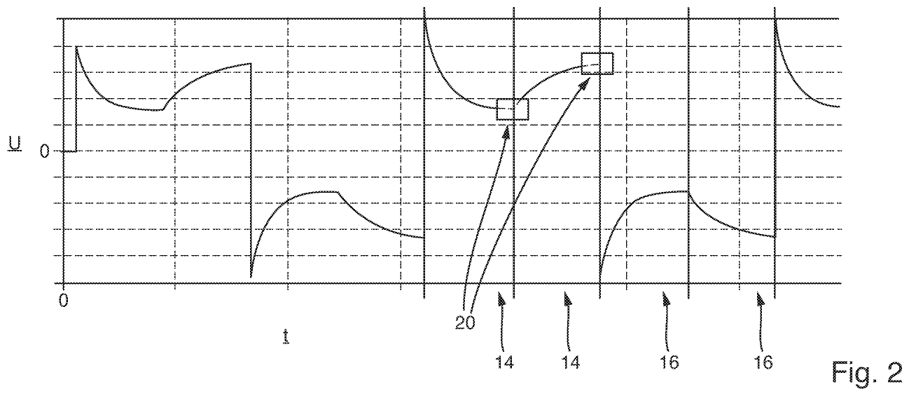

FIG. 2 illustrates an exemplary voltage measurement curve of a conventional insulation measurement in the normal state without insulation faults, wherein a high voltage U is applied with a small current between a connection line and the ground of the vehicle. The voltage U (in volts) is then measured over a predefined time t (in seconds). The measuring method constitutes a standard method, wherein, in this specific example, a parasitic capacitance of 1 μF per connection line and a resistance of 5000 kOhm in the case of a voltage of the battery system of around 403 V is assumed.

The voltage measurement is carried out for each connection line over a predefined time of 7 seconds, wherein first the positive pole 14 and then the negative pole 16 are measured, in each case with R0 (on the left) and successively with nominal resistance (on the right). As illustrated with the rectangular marking, at the end of the respective measurement, voltage saturation 20 occurs, wherein no further voltage change (that is relevant or within a predefined tolerance range) is measured at this time point. Based on these measurements and the achieved voltage saturation, according to this method, a resistance that characterizes the insulation state of the battery is calculated. It may be seen that such a method may require up to 30 seconds. Depending on the required accuracy, the resistance and the parasitic capacitance, the measurement may also last even longer.

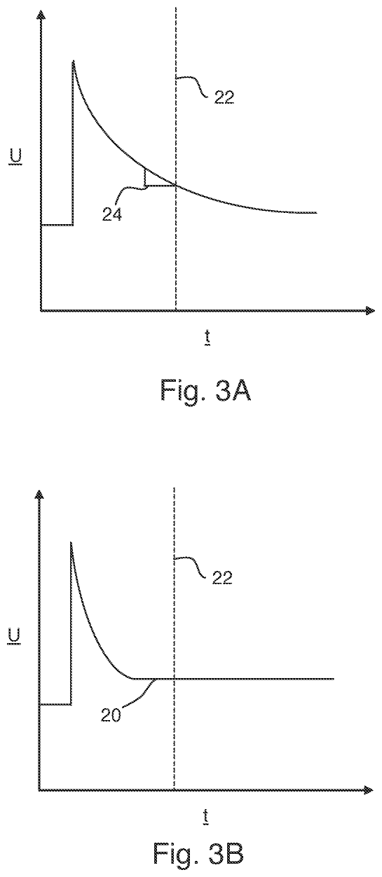

FIGS. 3A and 3B schematically illustrate the technical advantage of the checking method according to the invention. Based on a predefined parasitic capacitance, which is preferably measured and/or calculated or computed for the respective type of battery, and a predefined resistance, which is characteristic of at least one insulation fault, with a known voltage of the battery, a temporal threshold value 22 at which voltage saturation should occur in the event of the occurrence of a corresponding insulation fault is determined.

FIG. 3A illustrates a normal case in which no insulation fault is present. In this case, a voltage change 24 dU/dt is determined at the time point that corresponds to the temporal threshold value 22. From this it is determined that voltage saturation has not yet occurred at this time point and hence a (critical) insulation fault may be ruled out. In this case, it is possible to output a safety signal that indicates a fault-free state and it is possible, for example, to output an actuation signal for a high-voltage switching device in order to close the latter and provide an electrically conductive connection between the battery or the battery system and a load, such as an electric motor.

In FIG. 3B, however, an insulation fault or a small parasitic capacitance is present. The voltage saturation therefore occurs quickly—specifically before the temporal threshold value 22 has been reached and exceeded. In other words, no voltage change is established at the time point of the temporal threshold value 22 and a safety signal that indicates an insulation fault being present and/or that initiates a further alternative check of the insulation state is accordingly output. In other words, voltage saturation 20 has already occurred at the temporal threshold value 22.

In this manner a fast check of the insulation state is enabled that considerably reduces the waiting time for the user compared to resistance-based checking methods.

Where applicable, all individual features set forth in the exemplary embodiments may be combined with one another and/or exchanged without departing from the scope of the invention.

### LIST OF REFERENCE SIGNS

1 Battery system
10 Battery
12 Connection line or connection element
14 Positive pole
16 Negative pole
18 Chassis or ground
20 Voltage saturation
22 Temporal threshold value
24 Voltage change
U Voltage (V)
t Time (s)

1. A method for checking an insulation state of at least one of: a battery and a battery system comprising at least two batteries, comprising the following steps:
measuring a voltage between a connection element of the battery and a ground over a predefined time;
evaluating the measured voltage and determining whether a change in the measured voltage is present at a time point that corresponds to a predefined temporal threshold value; and
outputting a safety signal characterizing the insulation state on the basis of the determined result.

2. The method as claimed in claim 1, wherein that at least two connection elements are provided and the method is carried out for each connection element of the battery.

3. The method as claimed in claim 2, wherein the temporal threshold value is defined by a parasitic capacitance of at least one of: the battery and the battery system and a resistance of at least one of: the battery and the battery system.

4. The method as claimed in claim 3, wherein the parasitic capacitance is defined in a battery-specific manner.

5. The method as claimed in claim 4, wherein the parasitic capacitance is at least one of: measured and/or computed for at least one of: the battery and or the battery system.

6. The method as claimed in claim 5, wherein the resistance is between 50 kOhm and 250 kOhm.

7. The method as claimed in claim 6, wherein the resistance is at least one of: a predefined starting resistance and a nominal resistance.

8. The method as claimed in claim 7, wherein the voltage change is determined for at least one of: the last two to five measurement points, and when this has at least one predefined minimum magnitude.

9. The method as claimed in claim 8, wherein the safety signal is furthermore output on the basis of an absolute voltage value measured at the time point.

10. The method as claimed in claim 9, wherein in the event of a voltage change determined at the time point, the safety signal comprises at least one of: an actuation signal for a high-voltage switching device and, in the absence of a voltage change, a further insulation check.

11. A checking module for checking an insulation state of at least one of: a battery and a battery system, wherein the checking module is configured to:
measure a voltage between a connection element of the battery and a ground over a predefined time;
evaluate the measured voltage and determine whether a change in the measured voltage is present at a time point that corresponds to a predefined temporal threshold value; and
output a safety signal characterizing the insulation state on the basis of the determined result.

12. A battery system comprising at least two batteries and a checking module at least one of: communicatively and electrically conductively coupled thereto, wherein the checking module is configured to:
measure a voltage between a connection element of the battery and a ground over a predefined time;
evaluate the measured voltage and determine whether a change in the measured voltage is present at a time point that corresponds to a predefined temporal threshold value; and
output a safety signal characterizing the insulation state on the basis of the determined result.

13. The battery system as claimed in claim 12 comprising a high-voltage switching device that is configured to connect each battery on the basis of a safety signal output by the checking module.

14. The method as claimed in claim 1, wherein the at least two batteries comprise at least one of: a high-voltage battery and a high-voltage battery system for use as at least one of: a traction battery of an electric vehicle and in static storage applications

15. The method as claimed in claim 5, wherein the parasitic capacitance is increased by a predefined safety factor for determining the temporal threshold value.

16. The method as claimed in claim 6, wherein the resistance is between 75 kOhm and 175 kOhm.

17. The method as claimed in claim 8, wherein the voltage change is determined for the last two to three measurement points.

18. The checking module of claim 11, wherein the battery is a traction battery of an electric vehicle.
